(19) United States
(12) Patent Application Publication
(10) Pub. No.: US 2023/0334897 A1
(43) Pub. Date: Oct. 19, 2023

(54) BIOMETRICS SENSOR

(71) Applicant: Egis Technology Inc., Hsinchu City (TW)

(72) Inventors: BRUCE C. S. CHOU, Hsinchu City (TW); KUAN-YI LIN, Taipei City (TW); TONG-LONG FU, Hsinchu City (TW)

(21) Appl. No.: 18/043,403

(22) PCT Filed: Aug. 2, 2021
(86) PCT No.: PCT/CN2021/110043

§ 371 Date: Feb. 28, 2023

Related U.S. Application Data
(60) Provisional application No. 63/075,472, filed on Sep. 8, 2020.
(60) Provisional application No. 63/112,058, filed on Nov. 10, 2020.

(51) Int. Cl. G06V 40/13; G06V 40/12

(52) U.S. Cl. CPC G06V 40/1318; G06V 40/1324; G06V 40/1365; H10K 59/65

(57) ABSTRACT

A biometrics sensor includes: a digital light-emitting module including a first region and a second region, wherein the first region outputs incident light; and a sensing module disposed below the digital light-emitting module, wherein in a first mode, the second region does not output light having a wavelength the same as a wavelength of the incident light, so that the digital light-emitting module provides a defective optical field to irradiate an object disposed above the digital light-emitting module, and light generated by the object responsive to the defective optical field is received by the sensing module.

### CROSS-REFERENCE TO RELATED APPLICATIONS

This application is a U.S. National Stage under 35 U.S.C § 371 of International Application No. PCT/CN2021/110043 filed on Aug. 2, 2021, which claims priorities of U.S. Provisional Application No. 63/075,472 filed on Sep. 8, 2020, and U.S. Provisional Application No. 63/112,058 filed on Nov. 10, 2020 under 35 U.S.C. § 119(e), the entire contents of which are hereby incorporated by reference.

### BACKGROUND OF THE INVENTION

### Field of the Invention

This disclosure relates to a biometrics sensor, and more particularly to a device for performing biometrics sensing using a defective optical field.

### Description of the Related Art

Today's mobile electronic devices (e.g., mobile phones, tablet computers, notebook computers and the like) are usually equipped with user biometrics recognition systems including different techniques relating to, for example, fingerprint, face, iris and the like, to protect security of personal data. Portable devices applied to mobile phones, smart watches and the like also have the mobile payment function, which further becomes a standard function for the user's biometrics recognition. The portable device, such as the mobile phone and the like, is further developed toward the full-display (or super-narrow border) trend, so that conventional capacitive fingerprint buttons can no longer be used, and new minimized optical imaging devices, some of which are very similar to the conventional camera module having complementary metal-oxide semiconductor (CMOS) image sensor (referred to as CIS) sensing members and an optical lens module, are thus evolved. The minimized optical imaging device is disposed under the display as an under-display device. The image of the object (more particularly the fingerprint) placed above the display can be captured through the partial light-permeable display (more particularly the organic light emitting diode (OLED) display), and this can be called as fingerprint on display (FOD).

The FOD sensing needs to correctly sense the fingerprint, and also to judge whether the finger is real to prevent someone from passing through the authentication using the fake fingerprint or finger. At present, the spoofing technology is getting more and more refined. For example, a mold may be made from a 2D image or by 3D printing, and the mold is filled with various silica gels and pigments to produce the fake finger. Alternatively, another person's fingerprint may be copied into a transparent or skin-color film attached to the finger surface, so that the fake finger attached with the transparent film cannot be easily distinguished. Special attentions need to be paid on this fake finger recognition technology upon the FOD sensing because the display may shield partial characteristics of the finger to affect the recognition result.

According to the above-mentioned descriptions, the mechanism and method for judging the real finger need to be further improved to prevent the fake finger from passing through the fingerprint recognition.

### BRIEF SUMMARY OF THE INVENTION

It is therefore an objective of this disclosure to provide a biometrics sensor for sensing an optical reaction of an object including scattering, reflecting and/or light guiding properties in response to incident light of a defective incident light field provided by different regions of a digital light-emitting module, and obtaining data of recognizing whether the object is real or not.

To achieve the above-identified objective, this disclosure provides a biometrics sensor including: a digital light-emitting module including a first region and a second region, wherein the first region outputs incident light; and a sensing module disposed below the digital light-emitting module, wherein in a first mode, the second region does not output light having a wavelength the same as a wavelength of the incident light, so that the digital light-emitting module provides a defective optical field to irradiate an object disposed above the digital light-emitting module, and light generated by the object responsive to the defective optical field is received by the sensing module.

With the above-mentioned embodiment, the optical reaction of the object in response to the incident light of the defective incident light field can be detected, and function as a basis for judging the spectrum properties and/or judging whether the object is real or not.

In order to make the above-mentioned content of this disclosure more obvious and be easily understood, preferred embodiments will be described in detail as follows in conjunction with the accompanying drawings.

### BRIEF DESCRIPTION OF THE SEVERAL VIEWS OF THE DRAWINGS

FIG. 1 is a schematic view showing a biometrics sensor according to a first embodiment of this disclosure.

FIG. 2 is a schematic view showing a digital light-emitting module applicable to FIG. 1.

FIG. 3 is a top view showing a light-emitting state of the digital light-emitting module.

FIG. 4 is a schematic view showing a sensing result of a real finger.

FIG. 5 is a top view showing another example of the light-emitting state of the digital light-emitting module.

FIG. 6 is a top view showing still another example of the light-emitting state of the digital light-emitting module.

FIG. 7 is a schematic view showing an object functioning as a waveguide and causing scattered light.

FIGS. 8A to 8C are schematic views showing three different patterns of scattered light.

### SYMBOLS

C1, C2, C3: intensity curve
d: radial dimension
ED: curve
F: object
F1: epidermis layer
F2: dermis layer
HG: curve
L1: incident light
L2: to-be-detected incident-point light
L3: scattered light
L4: specular reflection light
L6: to-be-detected diffusion light
P1: incident point
P2: position
10: digital light-emitting module
11: light-emitting unit
12: first region
12A: inner zone
12B: outer annular zone
12C: first middle annular zone
14: second region
14B: second middle annular zone
14C: third middle annular zone
14D, 14E: geometric region
20: sensing module
21: sensing chip
22: sensing pixel
23: incident-point sensing region
24: diffuse sensing region
25: optical module
30: processor
100: biometrics sensor

### DETAILED DESCRIPTION OF THE INVENTION

In this disclosure, the defective optical field is mainly utilized to perform the biometrics sensing, wherein the defective optical field is provided by a first region and a second region of a light-emitting module, wherein a wavelength of light emitted from the first region is different from a wavelength of light emitted from the second region, or wherein the first region emits light and the second region does not emit light. That is, the first region outputs specific light, while the second region does not output the specific light. The defective optical field irradiates different objects, which generate different scattering, reflecting, absorbing and/or transmitting conditions. The spectrum property of the object can be obtained according to the material and the spectral reflecting, scattering, absorbing and/or transmitting interactions of the object, or whether the object is real or not can be further judged. The defective optical field (also referred to as a non-uniform optical field) is provided by controlling one region to output the specific light, and another region not to output the specific light, so that the spectrum sensing result obtained after reflecting, scattering and absorbing and/or obtained from a secondary output light field can be sensed, wherein the secondary output light field is defined as the optical field generated after the defective optical field has entered the object and then penetrated through the object, and thus includes the optical field generated after the incident light field has traveled a distance. The spectrum property of the material of the object can be determined according to the spectrum sensing result, and utilized to perform the anti-spoofing function of biometrics recognition, for example. However, this disclosure is not restricted thereto.

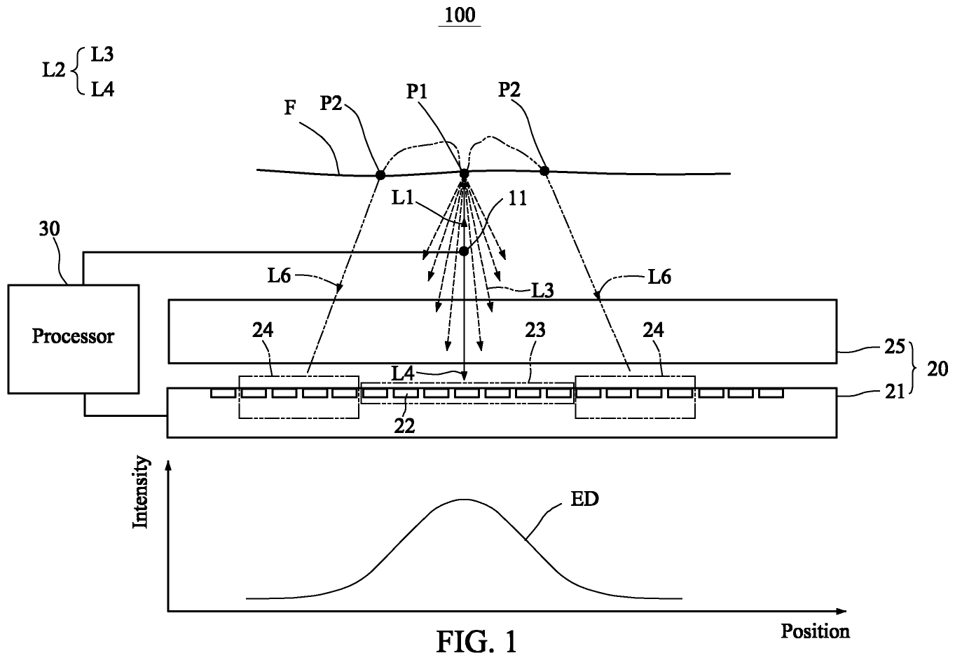

FIG. 1 is a schematic view showing a biometrics sensor according to a first embodiment of this disclosure, wherein a light-emitting unit 11 outputs light irradiating an object F, which is more particularly located nearer to the light-emitting unit 11, and generates scattering, reflecting, absorbing and/or transmitting conditions. A finger functioning as the object F will be described in the following, and this disclosure is not restricted thereto. Referring to FIG. 1, when incident light L1 of the light-emitting unit 11 irradiates an incident point P1 of the finger, the finger outputs to-be-detected reaction light, which includes to-be-detected incident-point light L2 and to-be-detected diffusion light L6, in response to the incident light L1. The light L2 includes scattered light L3 and specular reflection light L4 respectively scattered and specularly reflected by the skin. In addition, partial light penetrates through the skin and enters the finger, and multiple scattering and reflecting occur in the finger, so that the isotropic or anisotropic forward diffusion similar to light diffusing outward from the incident point P1 occurs. Also, since the light is outputted from the position P2 on the skin surface away from the incident point P1 due to the various effects, the light may be referred to as the to-be-detected diffusion light L6. Of course, the to-be-detected diffusion light may also include the scattered light, but is summarized as the to-be-detected diffusion light L6 for simplicity. The intensity of the to-be-detected diffusion light L6 decreases with the increase of the distance from the incident point P1. Because different fingers have different surface roughnesses or light absorbing and penetrating properties, the to-be-detected incident-point light L2 and the to-be-detected diffusion light L6 can reflect the material property of the finger, or even may serve as the basis for the real-finger judgement. Of course, the light L2/L6 is only depicted for the simple description. Actually, the to-be-detected incident-point light includes the component of the to-be-detected diffusion light in the short diffusion distance because the to-be-detected diffusion light is continuously outputted and distributed outward from the incident point P1.

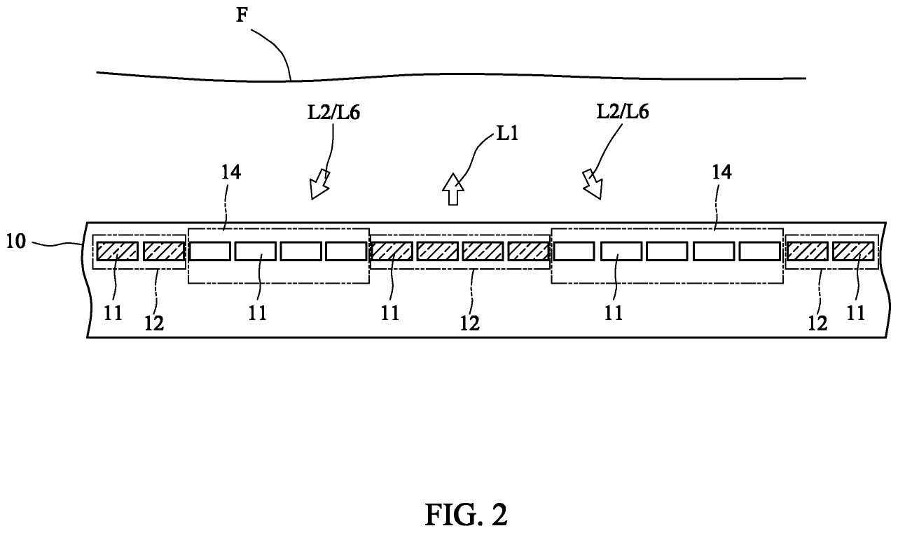

FIG. 2 is a schematic view showing a digital light-emitting module applicable to FIG. 1. Referring to FIGS. 2 and 1, in order to detect the to-be-detected reaction light, a biometrics sensor 100 including a digital light-emitting module 10, a sensing module 20 and an optional processor 30 may be designed. The light-emitting unit(s) 11 of FIG. 1 may constitute the digital light-emitting module 10 to provide a single-spectrum or multi-spectrum light source. The optional processor 30 represents that the processor 30 may be built in the biometrics sensor 100, and may also be a device externally connected to the biometrics sensor 100.

The digital light-emitting module 10 outputs light having the controllable brightness, spectrum and pattern, and may be controlled to have at least two regions including a first region 12 and a second region 14, for example. In one example, the digital light-emitting module 10 may be an organic light-emitting diode (OLED), a micro LED (,u LED) display or any other display capable of providing the digital light source, and has the light-emitting units 11, wherein the first region 12 includes light-emitting units 11, which are turned on to form a bright region; and the second region 14 includes the light-emitting units 11, which are turned off to form a dark region. In another example, the first region 12 and the second region 14 output different wavelengths of light, which may be identified by the sensing module in conjunction with different wavelengths of filters.

The sensing module 20 is disposed below the digital light-emitting module 10 (e.g., the display), and senses the biometrics characteristics of the object F above the digital light-emitting module 10. In this example, the sensing module 20 may be a fingerprint sensor, which may be a thin, lens type or in-cell optical fingerprint sensor of the OLED or μLED display, and the like. Of course, in another example, the sensing module 20 senses biometrics characteristics of the finger, such as the vein image, blood oxygen concentration image, and the like. It is understandable that the sensing module 20 may include a sensing chip 21 and an optical module 25 disposed above the sensing chip 21. The sensing chip 21 has sensing pixels 22 arranged in an array, wherein some of the sensing pixels 22 constitute an incident-point sensing region 23 for sensing the to-be-detected incident-point light L2, and some of the sensing pixels 22 constitute a diffuse sensing region 24 for sensing the to-be-detected diffusion light L6. Those skilled in the art may obtain that the incident-point sensing region 23 may receive some components of the to-be-detected diffusion light L6, and this still falls in the scope of this disclosure. The optical module 25 may be a lens-type optical engine, a collimator-type optical engine and the like. Because the to-be-detected incident-point light L2 is close to the incident-point sensing region 23, the intensity distribution of the incident-point sensing region 23 reaching the location thereunder is also similar to the original optical field at the incident point P1. The to-be-detected diffusion light L6 diffuses in the skin, for example, and then outputted therefrom, and is then sensed by the diffuse sensing region 24 disposed thereunder. It is understandable that the output intensity gets weaker as the diffusion distance gets longer. Thus, the optical intensity of the sensing signal obtained from the middle point of the incident-point sensing region 23 outward to the diffuse sensing region 24 gradually decreases with the increase of the distance in a manner similar to an exponential decay, as shown by a curve ED. Therefore, the spectrum property determination of the object F can be performed according to the optical intensities and curve distributions of the incident-point sensing region 23 and/or diffuse sensing region 24.

The processor 30 is directly or indirectly electrically connected to the digital light-emitting module 10 and the sensing module 20. In a first mode, the processor 30 controls the first region 12 to output the incident light L1 irradiating the object F, and controls the second region 14 not to output the light. The object F outputs the to-be-detected reaction light, sensed by the sensing module 20 to obtain a sensing signal, according to the incident light L1. Alternatively, the first region 12 and the second region 14 output different wavelengths of light, and filters for different wavelengths are disposed in the sensing module 20 to select the light having specific wavelengths to enter the sensing pixels 22. Therefore, the digital light-emitting module 10 has a portion outputting the incident light L1, and another portion, which does not output the light having the wavelengths the same as the wavelength(s) of the incident light L1, so that the second region 14 does not output the light having the wavelength(s) the same as the wavelength(s) of the incident light L1 of the first region 12. Thus, the defective optical field can be provided, so that the object F generates the light, which is defined as a reaction light generated in the first mode and received by the sensing module 20 to obtain the sensing signal, in response to the light of the defective optical field (including the incident light L1) through the digital light-emitting module 10. Because the optical reaction degree is determined by the material and roughness degree of the object's surface, the spectrum property of the object F can be determined according to the sensing signal, or even whether the object F is real can be further judged. The judgement basis may be obtained according to the database created by test data obtained by testing real and fake objects in the light-emitting state (first mode). In another example, the processor 30 further configures the relative positional relationship between the first region 12 and the second region 14, so that the to-be-detected incident-point light L2 and the to-be-detected diffusion light L6 may be well sensed to provide the more reliable determination and/or judgment result.

In a first example, the first region 12 outputs the specific spectrum of green light, and the second region 14 does not output light, so that the to-be-detected incident-point light L2 and the to-be-detected diffusion light L6 can be received by the sensing module 20 through the second region 14. The sensing result of the intensity distribution of the green light obtained by the sensing pixels 22 below the corresponding second region 14, the intensity and divergence angle of the to-be-detected incident-point light L2 and the transmission distance of the to-be-detected diffusion light L6 can be determined, and the spectrum property of the object F can be determined accordingly. In a second example, the first region 12 outputs the mixed spectrums of white light, and the second region 14 does not output light. In this state, the scattering condition of multiple spectrums of light is sensed, and the judgement and spectrum property determination the same as those of the first example may also be made according to the sensing result of the intensity distribution of the white light obtained by the sensing pixels 22. In a third example, the first region 12 outputs the specific spectrum of green light, and the second region 14 outputs the light having the wavelength(s) different from the wavelength(s) of the first region 12, the judgement and spectrum property determination the same as those of the first example may also be made according to the sensing result of the intensity distribution of the green light obtained by the sensing pixels 22.

In the first mode, the sensing result of some sensing pixels 22 may serve as the data for spectrum property determination and/or anti-spoofing recognition, and the sensing result of other sensing pixels may serve as the biometrics sensing data. Of course, the processor 30 may additionally configured to have a second mode (sensing mode) different from the first mode. In the sensing mode, the digital light-emitting module 10 is not divided into the light-emitting region (first region 12), and the region (second region 14) that does not output light. That is, the coverage range of the object F pertains to the light-emitting region. In addition, in the sensing mode, the sensing module 20 can obtain a second sensing signal representative of the biometrics characteristics of the object F, and the processor 30 compares the second sensing signal with the sensing signal to obtain the contributions of the to-be-detected incident-point light L2 and the to-be-detected diffusion light L6 to the second region 14, and the contribution may serve as the basis for judging the property of the object F (e.g., whether the object is real).

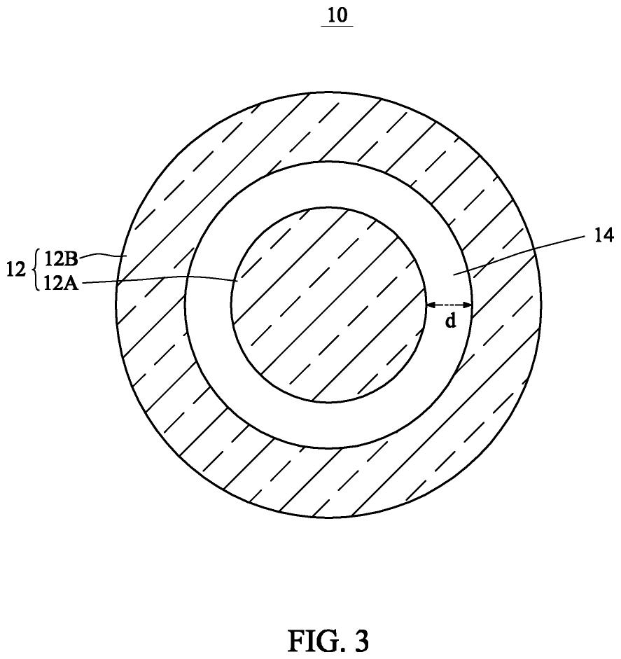

FIG. 3 is a top view showing the light-emitting state of the digital light-emitting module 10. Referring to FIG. 3, the first region 12 and the second region 14 provide an annular optical field. That is, an inner zone 12A and an outer annular zone 12B of the digital light-emitting module 10 constitute the first region 12, which emits light, and a middle annular zone between the inner zone 12A and the outer annular zone 12B constitute the second region 14, which does not output light and has a radial dimension d. In a fingerprint sensing example, the radial dimension d is greater than the fingerprint interval (about 300 to 400 microns).

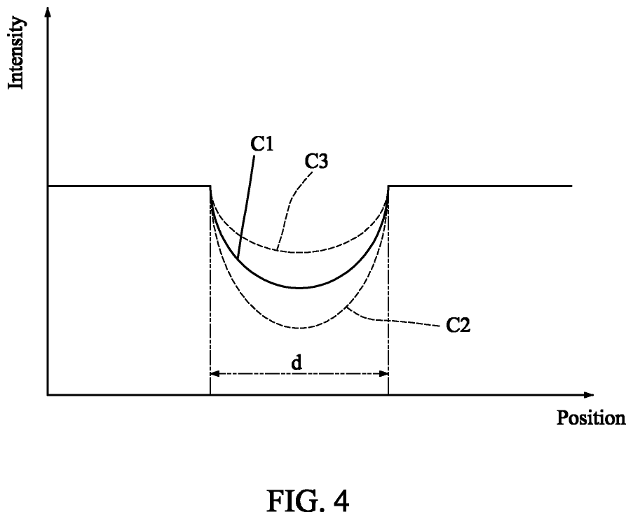

FIG. 4 is a schematic view showing a sensing result of a real finger, wherein the vertical axis represents the intensity of the sensing pixel, and the horizontal axis represents, from left to right, the position of the sensing pixel under or beneath the inner zone 12A of FIG. 3 to the position of the sensing pixel under the outer annular zone 12B. Referring to FIG. 4, a considerable difference is present between an intensity curve C1 of the real finger and an intensity curve C2 of the fake finger in the radial dimension d corresponding to the region which does not output the specific light, and the concave phenomenon of the intensity curve within the range of the radial dimension d represents the contribution of the first region, which outputs the specific light and is disposed outside the range of the radial dimension d, to the second region, which does not output the specific light. The contribution relates to the finger's property. If the second region and the first region output the same specific light, then the sensing result representative of the contribution cannot be obtained. The light scattering degree of the real finger is higher than that of the fake finger, so the intensity reduction degree at the location under the region, which does not emit light, is smaller than that of the fake finger. The real finger can be judged according to the intensity curve. Of course, there may be a contrary curve. That is, another intensity curve C3 is higher than the intensity curve C1. Because the real and fake fingers are relatively compared with each other without the absolute-value comparison, the intensity curves C2 and C3 on two sides of the intensity curve C1 of the real finger represent the material properties different from that of the real finger.

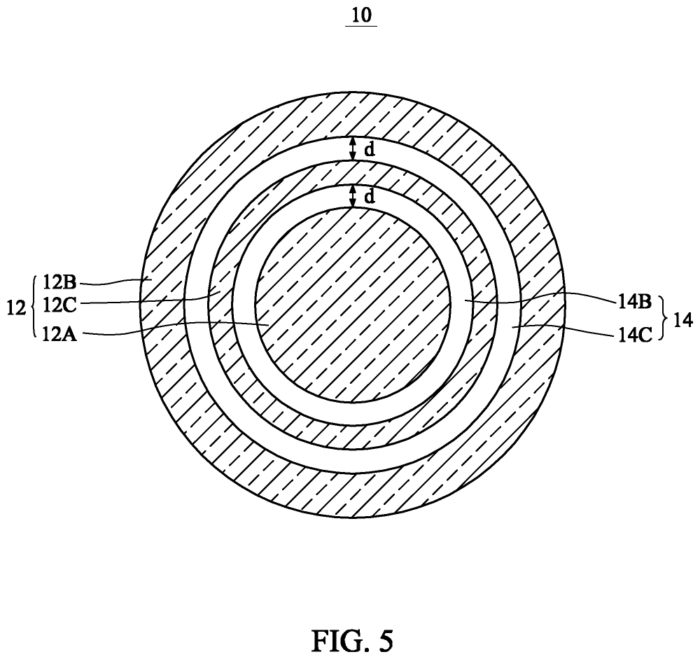

FIG. 5 is a top view showing another example of the light-emitting state of the digital light-emitting module. Referring to FIG. 5, this example is similar to FIG. 3 except for the difference that two middle annular zones constitute the second region. That is, the inner zone 12A, the outer annular zone 12B and a first middle annular zone 12C of the digital light-emitting module 10 constitute the first region 12 that emits light, and a second middle annular zone 14B and a third middle annular zone 14C among the inner zone 12A, the outer annular zone 12B and the first middle annular zone 12C constitute the second region 14 that does not output light. In one fingerprint sensing example, the radial dimension d of at least one of the second middle annular zone 14B and the third middle annular zone 14C is greater than the fingerprint interval.

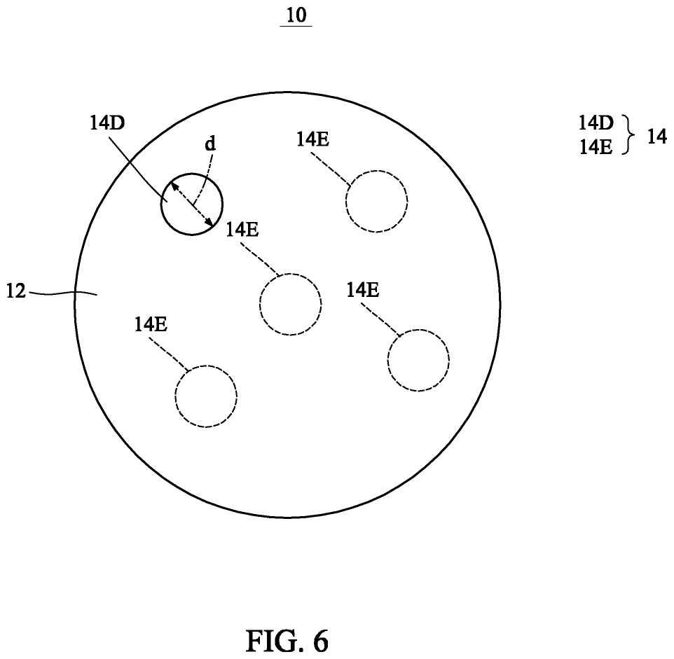

FIG. 6 is a top view showing still another example of the light-emitting state of the digital light-emitting module. Referring to FIG. 6, this example is similar to FIG. 3 except for the difference that the second region 14 includes at least one geometric region 14D, which may have a circular shape represented by a solid line, or any other geometric shape. Of course, in other examples, the second region 14 may further have geometric regions 14E represented by dashed lines. The configuration of multiple regions is that the data, which is sensed by the sensing module 20 and corresponds to the geometric regions 14D and 14E, can be accumulated and statistically counted to further enhance the identification stability. The effect of this disclosure may also be achieved by sensing the contribution of the to-be-detected reaction light to the geometric region 14D (14E). It is understandable that the contribution of the to-be-detected reaction light to the second region 14 may also be sensed using one single region, which has a circular, non-annular or any geometric shape and does not emit light, and the contribution functions as the property judgement basis of the object. In one fingerprint sensing example, the radial dimension of the geometric region 14D (14E) is greater than the fingerprint interval.

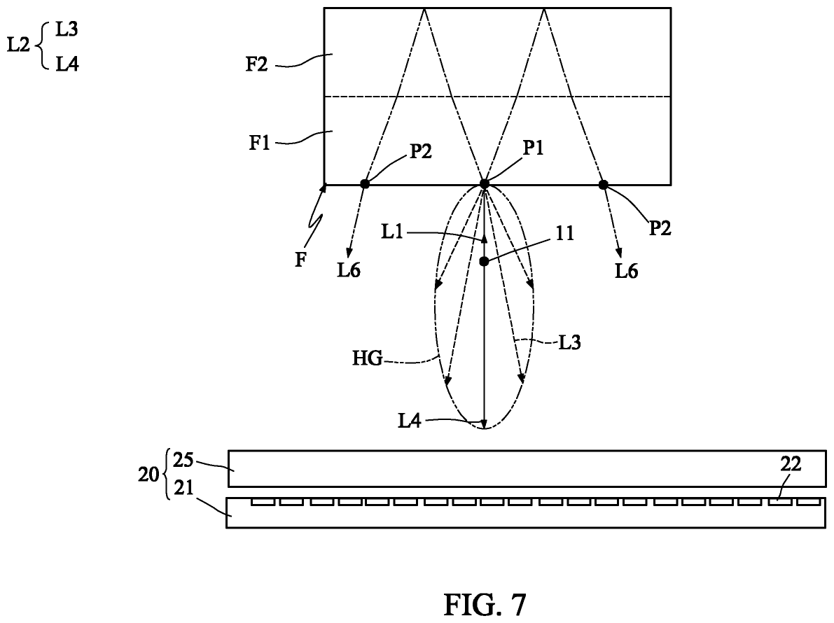

FIG. 7 is a schematic view showing an object functioning as a waveguide and causing scattered light. Referring to FIG. 7, the object F provides a waveguide for the incident light L1, and the incident light L1 having some incident angles enters a dermis layer F2 of the object F from an epidermis layer F1, and is then outputted as the to-be-detected diffusion light L6. In other words, the transmission distance of the incident light L1 is determined by the light-absorbing coefficient and/or spectrum property of the object F. Although the travelling paths in the epidermis layer F1 and the dermis layer F2 are represented by straight paths, this disclosure is not restricted thereto because tissues in the epidermis layer F1 and the dermis layer F2 still cause the isotropic or anisotropic forward diffusion condition. The transmission distance of the incident light L1 may be derived according to the sensing result (corresponding to the above-mentioned sensing signal) of the sensing pixels 22 of FIG. 7 with respect to the to-be-detected diffusion light L6. The light-absorbing coefficient and/or spectrum property, according to which the light guiding property of the object F can be obtained or the real object can be judged, may be determined according to the transmission distance.

In addition, the incident light having some incident angles scatters from the epidermis layer F1. According to Henyey-Greenstein phase function (Equation 1):

$$P ( θ ) , \qquad ( Equation 1 )$$

where P(θ) represents the intensity of the scattered light and forms a curve HG, σₛ represents the object's scattering coefficient, σₐ represents the object's light-absorbing coefficient, θ represents the angle of reflection of the to-be-detected incident-point light L2 and is defined as a scattering angle in the scattering condition, and g represents an anisotropy factor of the object's material, wherein different materials have different values of g. Whether the intensity distribution curve of the scattered light satisfies the known curve HG can be judged according to the sensing result of the sensing pixels 22 of FIG. 7 with respect to the to-be-detected incident-point light L2. Therefore, the material property can be determined according to an anisotropy level corresponding to the value of g. The function can be preferably applied to the sensing using a single-spectrum light source to obtain the anisotropic scattering effect.

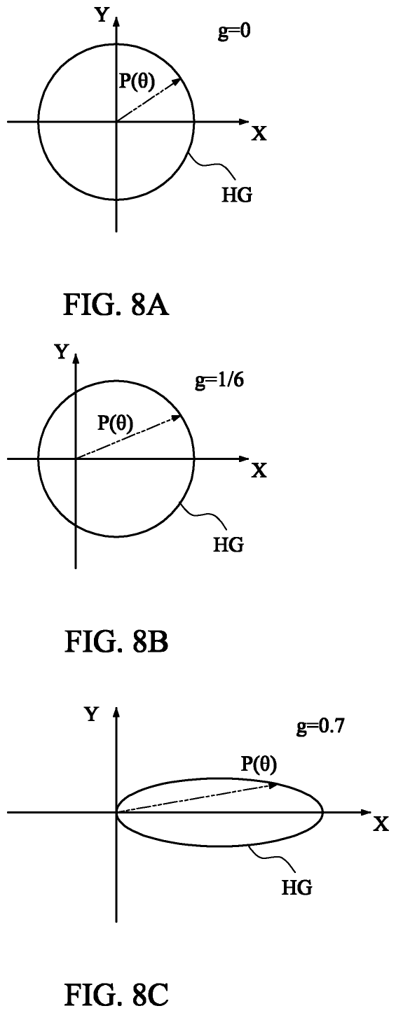

FIGS. 8A to 8C are schematic views showing three different patterns of scattered light. Referring to FIG. 8A, the scattered light corresponding to (g=0) has a circular intensity distribution with a center located at an origin of the X-Y coordinate system. Referring to FIG. 8B, the scattered light corresponding to (g=⅙) has a circular intensity distribution with a center disposed on a right side of the X-Y coordinate system, where the −X direction denotes the direction of the incident light. Referring to FIG. 8C, the scattered light corresponding to (g=0.7) has an elliptic intensity distribution, which has a center located on a right side of the origin of the X-Y coordinate system and a left vertex located at the origin of the X-Y coordinate system. A real finger has the value of g equal to about 0.7. Therefore, the processor 30 can derive a distribution of P(θ) according to the sensing results of the sensing pixels 22 of the FIGS. 8A to 8C, determine the value of g according to the distribution, and perform the real object judgement according to the value of g.

Therefore, the light guiding property of the object F can be determined according to the transmission distance of the incident light L1, and/or the anisotropy level of the object F can be determined according to the intensity distribution curve of the scattered light. Then, the database or contribution serves as the determination basis or real-object judgement basis for the spectrum property of the object F.

With the anti-spoofing biometrics sensor of the above-mentioned embodiment, it is possible to sense the sensing result of the object of scattering, reflecting, absorbing and/or light guiding properties in response to the incident light provided by the digital light-emitting module having a partial area, which emits light, in conjunction with another partial area, which does not emit light; or having a partial area, which emits specific light, in conjunction with another partial area, which does not emit the specific light. The sensing result can be compared with sensing data or any other database associated with real and fake objects in response to the non-defective optical field to provide the basis for judging the spectrum properties or judging whether the object is real or not.

The specific embodiments proposed in the detailed description of this disclosure are only used to facilitate the description of the technical contents of this disclosure, and do not narrowly limit this disclosure to the above-mentioned embodiments. Various changes of implementations made without departing from the spirit of this disclosure and the scope of the claims are deemed as falling within the following claims.

1. A biometrics sensor, comprising:
a digital light-emitting module comprising a first region and a second region, wherein the first region outputs incident light; and
a sensing module disposed below the digital light-emitting module,
wherein in a first mode, the second region does not output light having a wavelength the same as a wavelength of the incident light, so that the digital light-emitting module provides a defective optical field to irradiate an object disposed above the digital light-emitting module, and light generated by the object responsive to the defective optical field is received by the sensing module.

2. The biometrics sensor according to claim 1, wherein the second region does not output light.

3. The biometrics sensor according to claim 1, wherein the second region outputs light having a wavelength different from the wavelength of the incident light.

4. The biometrics sensor according to claim 3, wherein the sensing module comprises a filter for selecting light having a specific wavelength.

5. The biometrics sensor according to claim 1, wherein the object outputs to-be-detected reaction light according to the incident light, and the sensing module senses the to-be-detected reaction light to obtain a sensing signal.

6. The biometrics sensor according to claim 5, wherein the to-be-detected reaction light comprises:
to-be-detected incident-point light generated after a portion of the incident light has irradiated and been reflected by an incident point of the object; and
to-be-detected diffusion light generated after another portion of the incident light has entered the object, diffused forward, and outputted from a position away from the incident point.

7. The biometrics sensor according to claim 6, wherein the sensing module comprises:
an incident-point sensing region sensing the to-be-detected incident-point light; and
a diffuse sensing region sensing the to-be-detected diffusion light.

8. The biometrics sensor according to claim 6, further comprising a processor, which is electrically connected to the digital light-emitting module and the sensing module, derives a distribution of P(θ) according to the sensing signal, determines a value of g according to the distribution, and makes a judgement according to the value of g, wherein
$$P ( θ ) = ( \frac{{σ}_{s}}{{σ}_{s} + {σ}_{a}} ) \frac{( 1 - {g}^{2} )}{{( 1 + {g}^{2} - 2 g cos θ )}^{3 / 2}}$$
where P(θ) represents an intensity of the to-be-detected incident-point light, σₛ represents a scattering coefficient of the object, σₐ represents a light-absorbing coefficient of the object, θ represents an angle of reflection of the to-be-detected incident-point light, and g represents an anisotropy factor of the object.

9. The biometrics sensor according to claim 5, further comprising a processor electrically connected to the digital light-emitting module and the sensing module, wherein the processor further has a second mode different from the first mode, and in the second mode, the sensing module) obtains a second sensing signal representative of biometrics characteristics of the object, the processor compares the second sensing signal with the sensing signal to obtain a contribution of the to-be-detected reaction light to the second region, and a property of the object is determined according to the contribution.

10. The biometrics sensor according to claim 1, wherein the digital light-emitting module is an OLED display or a μLED display.

11. The biometrics sensor according to claim 1, wherein the first region and the second region provide an annular optical field as the defective optical field.

12. The biometrics sensor according to claim 1, wherein the digital light-emitting module comprises:
an inner zone and an outer annular zone constituting the first region, wherein the second region is disposed between the inner zone and the outer annular zone.

13. The biometrics sensor according to claim 12, wherein the second region has a radial dimension greater than a fingerprint interval.

14. The biometrics sensor according to claim 1, wherein the digital light-emitting module comprises:
an inner zone, an outer annular zone and a first middle annular zone constituting the first region; and
a second middle annular zone and a third middle annular zone being disposed among the inner zone, the outer annular zone and the first middle annular zone, and constituting the second region.

15. The biometrics sensor according to claim 14, wherein at least one of the second middle annular zone and the third middle annular zone has a radial dimension greater than a fingerprint interval.

16. The biometrics sensor according to claim 1, wherein the second region comprises at least one geometric region having a radial dimension greater than a fingerprint interval.

17. The biometrics sensor according to claim 1, further comprising a processor electrically connected to the digital light-emitting module and the sensing module, wherein the processor determines whether the object is real or not according to a database, wherein the database is created by test data obtained by testing real objects and fake objects in the first mode.

18. The biometrics sensor according to claim 1, wherein the second region comprises multiple geometric regions, so that data corresponding to the multiple geometric regions and being sensed and obtained by the sensing module can be accumulated and statistically counted to increase identification stability.

19. The biometrics sensor according to claim 1, further comprising a processor, which is electrically connected to the digital light-emitting module and the sensing module, derives a transmission distance of the incident light of the defective optical field according to a sensing signal of the sensing module, determines a light-absorbing coefficient of the object according to the transmission distance, and obtains a light guiding property of the object according to the light-absorbing coefficient.

20. The biometrics sensor according to claim 1, wherein:
the object is a finger; and
in the first mode, the second region does not output light, so that the digital light-emitting module provides the defective optical field to irradiate the finger, which is disposed above the digital light-emitting module, and reacts with the defective optical field to generate reaction light received by the sensing module, wherein a portion of sensing pixels of a sensing chip of the sensing module disposed under the second region senses the reaction light to obtain data for spectrum property determination or anti-spoofing recognition, and another portion of the sensing pixels of the sensing chip senses the reaction light to obtain sensing data of a fingerprint image, a vein image or a blood oxygen concentration image.
